(19) United States
(12) Patent Application Publication
(10) Pub. No.: US 2005/0199876 A1
(43) Pub. Date: Sep. 15, 2005

(54) Display device having photosensor and method of fabricating the same

(75) Inventor: Shoichiro Matsumoto, Ogaki-city (JP)

Correspondence Address: Barry E. Bretschneider;Morrison & Foerster LLP, Suite 300, 1650 Tysons Boulevard, McLean, VA, 22102, US

(73) Assignee: Sanyo Electric Co., Ltd., Moriguchi-city (JP)

(21) Appl. No.: 11/050,452

(22) Filed: Feb. 4, 2005

(30) Foreign Application Priority Data
Feb. 6, 2004 (JP) 2004-031313
Jan. 19, 2005 (JP) 2005-11742

(51) Int. Cl. H01L 29/04

(52) U.S. Cl. 257/64

(57) ABSTRACT

When a photosensor was conventionally provided in a display device, separate modules manufactured in separate steps were installed in the same case. However, decreases in the number of parts and in cost could not be achieved, and a compact size and thinning of the display device was not proceeded. A photosensor is realized by a TFT provided on an insulating substrate. Photocurrent caused by incidence of external light onto a TFT when the TFT is turned-off is detected so that the TFT is used as a photosensor. By performing laser-annealing for a semiconductor layer of the photosensor, an average grain size of crystal particles of the semiconductor layer of the photosensor is made larger than those of a crystal particle of a display portion and a light emission element, thereby improving crystal properties. Thus, a generation efficiency of the photocurrent of the photosensor can be increased.

### BACKGROUND OF THE INVENTION

1. Field of the Invention

The present invention relates to a display device and a method of fabricating the same, and more particularly to a display device installing a photosensor in the same substrate and a method of fabricating the same.

2. Description of the Related Arts

As for current display devices, displays have been spread by demands for a compact size, light weight and thin thickness thereof from the market. Among such display devices, there haven been many devices installing a photosensor therein, which include, for example, an optical touch panel for detecting input coordinates by blocking light, and devices senses external light to control brightness of a display.

FIG. 9 shows an example of the optical touch panel. Optical touch panel 301 arranges light emitter 303 for emitting infrared ray and the like and light detector 304 for receiving the infrared ray and the like in the periphery of display plane 302. Such an optical touch panel 301 detects a point as input coordinates, from which the infrared ray does not reach to the light detector 304, by blocking the infrared rays emitted from the light emitter 303 with user's fingers which are trying to perform coordinate input. This technology is described for instance in Japanese Patent Application Publication No. Hei 5-35402 (page 2 to 2, FIG. 2).

In conventional displays, a display portion and a photosensor were manufactured as separate module parts after having undergone different manufacturing processes using separate production facilities. These separate module parts were assembled into the same case, and thus a finished product was manufactured. Therefore, there was inevitably a limitation to a decrease in the number of parts of the device and a reduction of a manufacturing cost for each module part.

Particularly, the dissemination of mobile terminal devices such as PDAs is currently remarkable, and therefore a further compacted size, lighter weight and thinner thickness are required for the displays. Accordingly, a decrease in the number of parts and provision of cheap displays are desired.

### SUMMARY OF THE INVENTION

The invention provides a display device that includes a display portion comprising a plurality of pixels, each of the pixels comprising a first thin film transistor comprising a first semiconductor layer, and a photosensor comprising a second thin film transistor comprising a second semiconductor layer, wherein a grain size of crystals forming the second semiconductor layer is larger than a grain size of crystals forming the first semiconductor layer.

The invention also provides a display device that includes a display portion comprising a plurality of pixels, each of the pixels comprising a first thin film transistor comprising a first semiconductor layer, and a photosensor comprising a second thin film transistor comprising a second semiconductor layer, wherein a crystal length in a predetermined direction of crystals forming the second semiconductor layer is longer than a crystal length in the predetermined direction of crystals forming the first semiconductor layer.

The invention further provides a method of fabricating a display device. The method includes forming an amorphous semiconductor layer on an insulating substrate, crystallizing the amorphous semiconductor layer so as to form a first semiconductor layer of a first grain size and a second semiconductor layer of a second grain size that is larger than the first grain size, forming a first thin film transistor comprising the first semiconductor layer, forming a photosensor comprising a second thin film transistor comprising the second semiconductor layer, and forming a pixel comprising the first thin film transistor in a display portion of the display device.

The invention further provides a method of fabricating a display device. The method includes forming an amorphous semiconductor layer on an insulating substrate, crystallizing the amorphous semiconductor layer so as to form a first semiconductor layer comprising crystals having a first crystal length in a predetermined direction and a second semiconductor layer comprising crystals having a second crystal length in the predetermined direction which is longer than the fist crystal length, forming a first thin film transistor comprising the first semiconductor layer, forming a photosensor comprising a second thin film transistor comprising the second semiconductor layer so that an electric conduction of the second thin film transistor is in the predetermined direction, and forming a pixel comprising the first thin film transistor in a display portion of the display device.

According to the display device of the present invention, an average grain size of crystal particles of a semiconductor layer in a TFT functioning as a photosensor is set to be larger than a semiconductor layer in a TFT constituting a display portion and a light emission element, whereby a probability of occurrence of electron-hole pairs increases during light radiation, and crystal properties are improved. Thus, very small current can be detected more easily.

Particularly, since a high precision photosensor can be materialized with a TFT formed in an insulating substrate, the photosensor can be arranged in the same substrate where a display device is formed, and a compacted size and thin thickness of the device can be realized. Since enlargement of the average grain size of crystal particles can be realized by performing laser-annealing only for the photosensor portion two times, such enlargement can be carries out without complicating fabrication processes, and can be further contributed to decreases of the numbers of parts and fabrication processes compared to a structure in which the photosensor is installed as a separate module.

Furthermore, the grain size of a crystal particle of the TFT constituting the display portion and the light emission element should not be made large beyond necessity. By performing the laser-annealing two times only for the photosensor portion which is a region fully smaller than the display portion, it is possible to provide the method of fabricating a display device, which is capable of detecting very small photocurrent while preventing an increase in cost.

### BRIEF DESCRIPTION OF THE DRAWINGS

FIG. 1A and FIG. 1B are a plan view of a touch panel and a section view taken along the line B-B of FIG. 1A.

FIG. 2A and FIG. 2B are a plan view of one pixel in a display portion and a section view taken along the line B-B of FIG. 2A.

FIG. 3 is a section view of a photosensor.

FIG. 4 is a section view for explaining a method of fabricating a display device according to an embodiment of the invention.

FIG. 5 is a section view for explaining a method of fabricating a display device according to an embodiment of the invention.

FIG. 6 is a section view for explaining a method of fabricating a display device according to an embodiment of the invention.

FIG. 7 is a section view for explaining a method of fabricating a display device according to an embodiment of the invention.

FIG. 8 is a section view for explaining a method of fabricating a display device according to an embodiment of the invention.

FIG. 9 is a section view for explaining a conventional art.

### DETAILED DESCRIPTION OF THE PREFERRED EMBODIMENTS

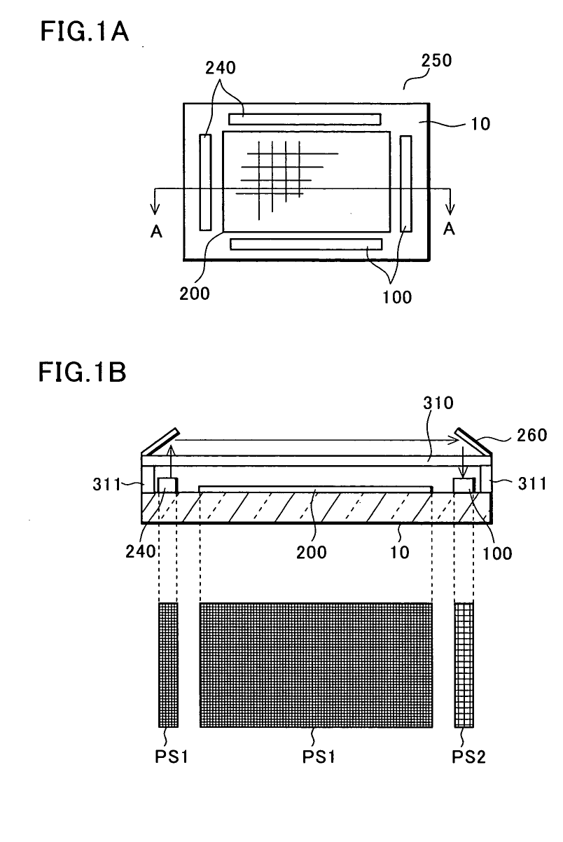

A first embodiment of the present invention will be described with reference to FIGS. 1 though 8 in detail while taking a touch panel using an organic EL element as an example. FIG. 1A is a plan view of a touch panel, and FIG. 1B is a section view taken along the line A-A of FIG. 1A. Note that a reflection material of FIG. 1B is omitted in FIG. 1A.

Display device 250 of this embodiment of the present invention comprises photosensor 100, display portion 200 and light emission element 240, which are arranged in the same insulating substrate 10.

The display portion 200 has a switching TFT and a driving TFT, and arranges a plurality of pixels formed of an organic EL element in a matrix therein, which is connected to the driving TFT. The plurality of light emission elements 240 are arranged along two sides at the periphery of the display portion 200. The light emission elements 240 are arranged, for example, in a rectangular region of FIG. 1A at certain intervals, and the photosensors 100 receive light emitted from the corresponding light emission elements 240. Each of the light emission element 240 is formed of an organic EL element which is identical to that constituting the display portion 200. Alternatively, when it is intended to active-drive each of the light emission element 240, a TFT constituting the display portion 200 may be further provided in the organic EL element. The photosensors 100 are a TFT, and arranged along opposite two sides of the display portion 200, which are different from those where the light emission elements 240 are arranged. The plurality of photosensors 100 are arranged at certain intervals so as to correspond respectively to the light emission elements 240 in the rectangular region of FIG. 1A.

As shown in FIG. 1B, the display portion 200, the light emission elements 240 and the photosensors 100 are sealed by transparent cover material 310, such as glass, while interposing sealing material 311 provided in the periphery of the substrate therebetween.

Each of the light emission elements 240 emits light in the upward direction perpendicularly to the plane of the display portion 250 illustrated in FIG. 1B. Therefore, reflection material 260 such as an mirror is provided on the substrate 10 so that the light from the light emission element 240 travels above the display portion 200 and reaches the photosensor 100. Note that a grain size of a crystal particle of the semiconductor layer constituting each TFT is schematically illustrated below the substrate 10 of the drawing. In this embodiment, each TFT is constituted by the first semiconductor layer ps1 and the second semiconductor layer ps2, which have different grain size of a crystal particle, and descriptions as to the grain size of a crystal particle will be made later.

Describing an example of a method of detecting input coordinates, among the light emission elements 240, each of the light emission elements 240 arranged in one side of the display portion 200 first performs light emission sequentially in the order thereof, and subsequently each of the light emission elements 240 arranged in the other side thereof performs light emission sequentially in the order thereof. If there exists no body above the display portion 200, the light emitted from each of the light emission elements 240 is always received by the photosensor 100. Meanwhile, when fingers and an entering pen touch a predetermined position of the display portion 200, the light emission of a specific light emission element 240 is blocked, and the light emitted from the specific light emission element 240 comes not to be received by a specific photosensor 100. The region blocking the light is two-dimensionally sensed based on a timing of the light emission of the specific light emission element 240 and an output of the specific photosensor 100, and thus input coordinates are detected.

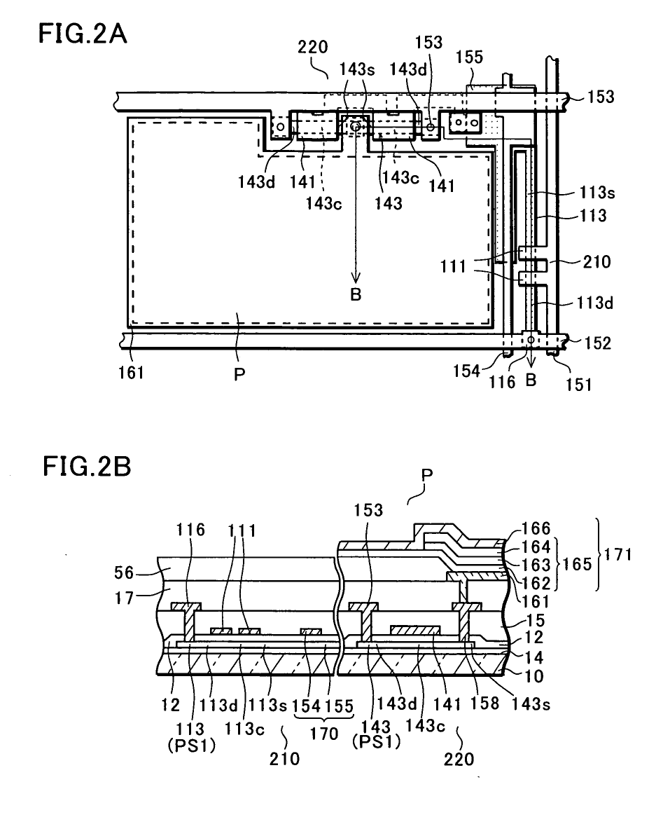

FIGS. 2A and 2B show one pixel of the display portion of FIGS. 1A and 1B. FIG. 2A is a plan view, and FIG. 2B is a section view taken along the line B-B of FIG. 2B.

As shown in FIG. 2A, each of pixels P is formed in a region surrounded by gate signal line 151 and drain signal line 152. Switching TFT 210 is provided in the vicinity of an intersection of both signal lines, and source 113s of the TFT 210 functions also as capacitor electrode 155. The capacitor electrode 155 constitutes holding capacitor 170 together with holding capacitor electrode line 154 to be described later. The source 113s is connected to gate 141 of driving TFT 220 of organic EL element 171. Source 143s of the driving TFT 220 is connected to anode 161 of the organic EL element 171, and drain 143d is connected to driving power supply line 153 for driving the organic EL element.

Furthermore, the holding capacitor electrode line 154 is arranged in parallel with the gate signal line 151 in the vicinity of the switching TFT 210. This holding capacitor electrode line 154 stores charges between itself and the capacitor electrode 155 through gate insulating film 12, and constitutes the holding capacitor 170. The holding capacitor 170 is provided so as to hold a voltage applied to the gate 141 of the driving TFT 220. The capacitor electrode 155 is connected to the source 113s of the switching TFT 210.

As shown in FIG. 2B, the switching TFT 210 provides insulating film 14, which functions as a buffer layer, on the insulating substrate 10 made of quartz glass, non-alkali glass and the like. Semiconductor layer 113 formed of the first p-Si film ps1 is formed on the insulating substrate 10. In the semiconductor layer 113, channel 113c which is intrinsic or substantially intrinsic is provided on a region overlapping a gate electrode 111. The source 113s and the drain 113d are provided on both sides of the channel 113c. Furthermore, the semiconductor layer 113 may be so called a LDD (lightly doped drain) structure. In this case, both sides of the channel 113c is a low concentration impurity region, and the outside of both sides thereof is a high concentration impurity region.

The gate insulating film 12 is provided on the semiconductor layer 113, and the gate signal line 151 (not shown here) functioning also as the gate electrode 111 made of a high melting point metal, and the holding capacitance electrode line 154 are also provided on the gate insulating film 12.

Interlayer insulating film 15 is laminated on the entire surfaces of the gate insulating film 12, the gate electrode 111, the gate signal line 151 and the holding capacitor electrode line 154, and a metal is filled in a contact hole of the gate insulating film 12 and the interlayer insulating film 15, which is provided so as to correspond to the drain 113d, and thus drain electrode 116 functioning as the drain signal line 152 is provided. Note that the source 113s is extended so as to form the holding capacitor 170.

The second TFT 220 is provided on the insulating substrate 10 and the buffer layer 14, where the switching TFT 210 is formed. Specifically, a semiconductor layer 143 formed of the first p-Si film ps1 is provided. In the semiconductor layer 143, a channel 143c which is intrinsic or substantially intrinsic is formed in the semiconductor layer 143, and both sides of the channel 143c undergoes ion-doping, and thus the source 143s and the drain 143d are formed on both sides of the channel 143c in the semiconductor layer 143.

The gate insulating film 12 and the gate electrode 141 made of a high melting point are formed on the semiconductor layer 143.

Subsequently, the interlayer insulating film 15 is formed as in the case of the switching TFT 210, and a metal is filled in a contact hole provided so as to correspond to the drain 143d, and thus the driving power supply line 153 connected to a driving power supply is arranged. Furthermore, source electrode 158 is provided in the contact hole provided so as to correspond to the source 143s. Planarized insulating film 17 is formed on the entire surface of the resultant structure, and a contact hole is formed at a position in the planarized insulating film 17 corresponding to the source electrode 158. A first electrode having a reflection function by mixing Ag compound into ITO (indium tin oxide) and IZO (indium zinc oxide), which contacts the source electrode 158 through the contact hole, that is, the first electrode (anode) 161, is provided. The organic EL element 171 is constituted by the first electrode 161, organic EL layer 165 and second electrode 166.

The organic EL layer 165 is formed by laminating hole transportation layer 162, light emission layer 163 and electron transportation layer 164 on the anode 161 in this order. Furthermore, the second electrode, that is, cathode 166, which is made of magnesium indium alloy and made thin in its thickness so as to transmit light therethrough, is laminatedly formed thereon. The cathode 166 is provided on the entire surface of the substrate 10 forming an organic EL display portion shown in FIG. 2A. Furthermore, the light emission layer 163 emits R, G and B color lights by using different materials for each pixel.

In the organic EL element 171, holes injected from the anode 161 and electrons injected from the cathode 166 are recombined within the light emission layer 163, and organic molecules forming the light emission layer 163 are excited, thus generating excitons. Light is emitted from the light emission layer 163 in the course these excitons are radiated to be inactivated, and this light is emitted from the cathode 166 having light permeability to the outside, so that light emission is performed by the organic EL element 171.

Since the light emission element 240 may use the same constituent components as those of the above described pixel, illustrations and detailed descriptions are omitted. Specifically, the buffer layer 14, the semiconductor layer formed of the first p-Si film ps1, the gate insulating film and the gate electrode are laminated on the substrate, and the channel, the source and the drain are provided in the semiconductor layer. The drain electrode connected to the drain and the source electrode connected to the source are provided, and thus the organic EL element is formed. The organic EL element has a structure that the organic EL layer is formed on the anode and the cathode is laminated thereon. The anode is connected to the source electrode.

However, the light emission layer of the pixel emits any of three color lights of R, G and B, as described above, and the pixels are arranged sequentially in order. Meanwhile, the light emission element may emits light simply, and may emit one color lights. For example, since it is necessary to allow the light to pass above the display portion 200 to reach the photosensor 100, the light emission element should emit strong light as possible, and a light emission element emitting the blue color (B) light with high energy in terms its waveform should be employed.

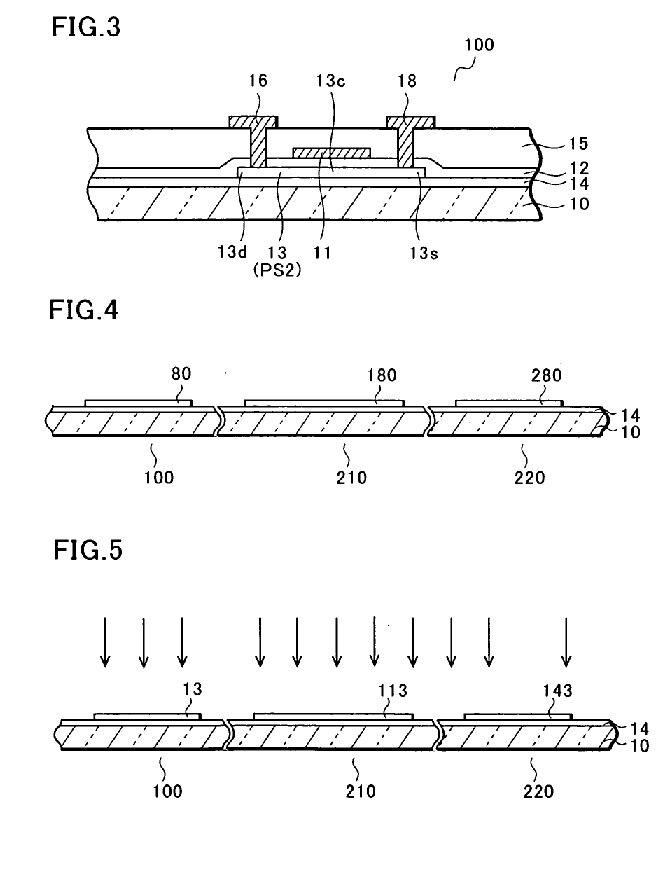

FIG. 3 is a section view showing the photosensor 100. The photosensor 100 is a TFT constituted by a gate electrode 11, the insulating film 12 and a semiconductor layer 13.

The photosensor 100 provides the buffer layer 14 on the insulating substrate 10 where the display portion 200 is formed, and the semiconductor layer 13 formed of the second p-Si film ps2 and the gate insulating film 12 are laminated thereon. On the gate insulating film 12, the gate electrode 11 made of a high melting point metal such as chromium (Cr) and molybdenum (Mo) is provided.

The semiconductor layer 13 of the photosensor 100 is formed of the second p-Si film ps2 having the grain size of a crystal particle larger than that of the first p-Si film ps1 (semiconductor layers 113, 143) of each TFT constituting the display portion 200 and the light emission element 240. To be concrete, when the one obtained by averaging grain size of crystal particles of the plurality of p-Si crystals contained in a unit area is called an average grain size of crystal particles, the average grain size of crystal particles of the semiconductor layer 13 which is the second p-Si film ps2 shall be larger than that of the semiconductor layers 113 and 143 of the display portion and the light emission element, which are the first p-Si film ps1 (see FIG. 1B).

In the semiconductor layer 13, a channel 13c which is located below the gate electrode 11 and intrinsic or substantially intrinsic is provided, and a source 13s and a drain 13d, which are an n⁺-type diffusion region, are provided on both sides of the channel 13c.

The interlayer insulating film 15, in which a SiO₂ film, a SiN film and a SiO₂ film are laminated in this order, is provided on the entire surfaces of the semiconductor layer 13, the gate insulating film 12 and the gate electrode 11. Furthermore, a drain electrode 16 connected to the drain 13d is provided. A source electrode 18 connected to the source 13s is provided, and the planarized insulating film 17 (not shown here) is provided on the drain and source electrodes 16 and 18.

Photo current amplified by the photosensor 100 is outputted from the source electrode 18 side or the drain electrode 16 side.

The plurality of photosensors 100 are provided so as to correspond to the respective light emission elements 240. When the plurality of photosensors 100 are arranged in this manner, the photosensors 100 are connected in parallel with each other. By providing the plurality of TFTs, redundancy and averageness of light receiving as the photosensors 100 are secured.

In the TFT having the above described structure, when light is incident onto the semiconductor layer 13 from the outside during turning-off of the TFT, a junction region occurs in the vicinity of the boundary between the channel 13c and the source 13s or between the channel 13c and the drain 13d. In the junction region, electron-hole pairs are separated by electric field, and photoelectromotive force is generated. Thus, photocurrent is obtained. The TFT is utilized as the photosensor by detecting an increase of such photocurrent.

However, when carriers (electrons or holes) move between grain boundaries, large energy is required. Furthermore, an amount of resistance components increases due to traps of the carriers at the grain boundaries. Particularly, in the touch panel shown in FIGS. 1A and 1B, light from the light emission element 240 is reflected and the light passing through the display portion 200 is received by the photosensor 100. Specifically, attenuation of the light caused until the light reaches the photosensor 100 is unavoidable, and the photosensor 100 senses very weak light.

Accordingly, as in the case of this embodiment, by making the average grain size of crystal particles of the semiconductor layer 13 of the photosensor 100 large, the number of times of movements of the carriers between the grain boundaries becomes small, and the grain boundaries in an electric conduction direction also decrease. Since a crystal property of the semiconductor layer 13 is improved by approximating a crystallinity of the semiconductor layer 13 to that of a single crystal, a probability of occurrence of electron-hole pairs increases during light irradiation, and it is possible to sense even very small current.

On the other hand, drivability of the TFT constituting the display portion 200 and the light emission element 240 may be sufficiently equal to that of a semiconductor layer polycrystallized by a known crystallization process in terms of its operation speed. That is, to improve the current drivability unnecessarily is not desirable because it is thought that variations of TFT characteristics such as drivability of the TFT becomes large. Furthermore, if the grain size of a crystal particle is made large, the TFT may be formed on the crystal boundaries. Such a TFT is apt to cause breaking and short-circuiting, leading to a problem of pixel defect.

Accordingly, in this embodiment, the average grain size of crystal particles of the semiconductor layer 13 of the TFT constituting the photosensor 100 is made larger than those of the semiconductor layers 113 and 143 of the switching and driving TFTs 210 and 220 provided in the display portion 200, as shown in FIG. LA When a TFT for active-driving the light emission element 240 is present, the average grain size of crystal particles of the semiconductor layer 13 thereof is also made larger than that of a semiconductor layer forming this TFT. Even when TFTs positioned in grain boundaries exist by making the grain size of a crystal particle large, the plurality of photosensors are coupled to each other in parallel, and hence the characteristics of light receiving of the photosensors are averaged, sense capability of them are only slightly influenced.

Next, a method of fabricating a displaying device according to an embodiment of the present invention will be described by use of FIGS. 4 through 8. Although the TFT constituting light emission element 240 and the TFT constituting the photosensor 100 may be formed in different processes from the following processes, these TFTs are formed in the same processes as the following processes in this embodiment. Furthermore, since the light emission element 240 has the same structure as that of the driving TFT, illustrations and descriptions are omitted.

First Process (See FIG. 4): Process of Forming an Amorphous Semiconductor Layer on an Insulating Substrate

A buffer layer 14 made of SiN, SiO₂ and the like is formed on a insulating substrate 10 made of quartz glass, non-alkali glass and the like, and an amorphous silicon film is deposited on the buffer layer 14, followed by patterning the amorphous silicon film. Thus, amorphous semiconductor layers 80, 180 and 280 respectively used for constituting switching TFT 210, driving TFT 220 and TFT of the photosensor 100 are formed.

Second Process (See FIG. 5): Process of Polycrystallizing Amorphous Semiconductor Layer

The amorphous semiconductor layers are polycrystallized by laser-annealing, and thus semiconductor layers 113 and 143 constituting the switching TFT 210 and the driving TFT 220, and a semiconductor layer 13 constituting the photosensor 100 are formed. In this state, the semiconductor layers have grain size of a crystal particle equal to each other.

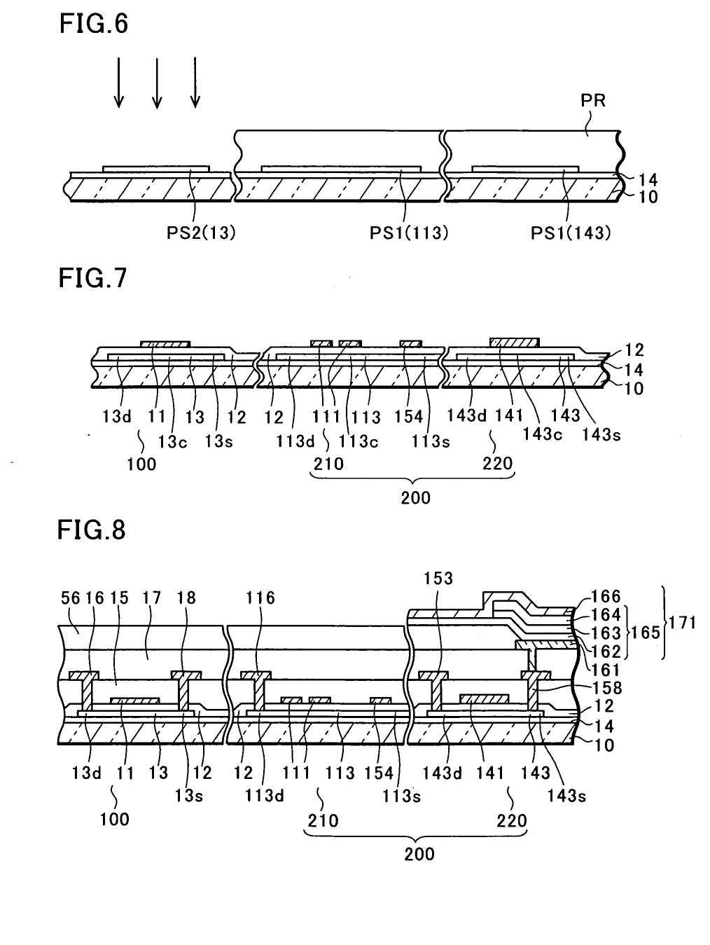

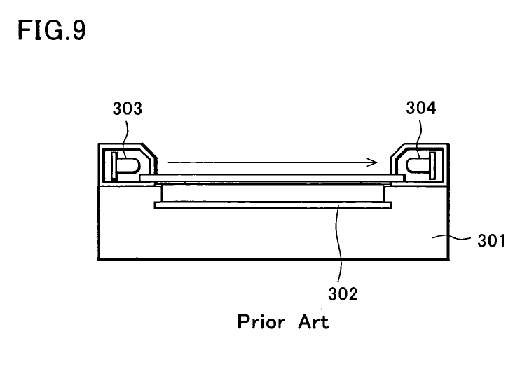

Third Process (See FIG. 6): Process of Forming First and Second Semiconductor Layers Having Different Grain Size of a Crystal Particle by Crystallizing Parts of Polycrystallized Semiconductor Layer

Resist film PR is formed, and only the semiconductor layer 13 of the photosensor 100 is exposed. Laser annealing is performed again, and the grain size of a crystal particle is enlarged. Thus, a first p-Si film ps1 and a second p-Si film ps2 having the grain size of a crystal particle different from each other are formed. An average grain size of crystal particles of the second p-Si film ps2 (semiconductor layer 13) is larger than that of the first p-Si film ps1 (the semiconductor layers 113 and 143).

In this embodiment, although a method is used, in which resist mask PR is formed and a laser is radiated onto the entire region of the resultant structure to enlarge the grain size of a crystal particle selectively, other methods achieving the same effects as this method may be employed. For example, regions where the grain size of a crystal particle are different from each other may be formed by limiting a region onto which the laser is radiated, by changing the number of times of laser radiations, and by changing an amount of energy given to each of semiconductor layers by the laser radiation. Furthermore, a scanning speed for the laser radiation is decreased for a region where a photosensor is formed, or alternatively a laser output is changed, whereby the amount of the energy given to the semiconductor layer by the laser radiation may be changed.

Fourth Process (See FIG. 7): Process of Forming First Thin Film Transistor Having First Gate Electrode and First Semiconductor Layer

SiN, SiO₂ or the like, which constitutes gate insulating film 12, is formed on the buffer layer 14 and the semiconductor layer 113, and a high melting point metal such as Cr, and Mo is evaporated thereon, thus forming a gate electrode 111. Note that a holding capacitor electrode line 154 for forming a holding capacitor may be formed at a predetermined position on the semiconductor layer 113 which is the first p-Si film ps1. Subsequently, a region of the semiconductor layer 113 overlapping the gate electrode 111, the semiconductor layer 113 constituting the switching TFT 210, is used as channel 113c, and one conductivity type impurities of a high concentration are diffused onto both sides of the channel 113c, thus forming the source 113s and drain 113d. Furthermore, the semiconductor layer 113 may be formed to so-called a LDD (lightly doped drain) structure. In this case, one conductivity type impurities of a low concentration are diffused onto both sides of the channel 113c at a low concentration, and impurities of a high concentration are diffused onto both sides of the channel 113c.

In the same manner described above, the gate insulating film 12 and a gate electrode 141 are laminatedly formed on the buffer layer 14 and the semiconductor layer 143 which is the first p-Si film ps1, and thus the driving TFT 220 of the display portion 200 is formed. Subsequently, a channel 143c is formed in a region of the semiconductor layer 143 overlapping the gate electrode 141, the semiconductor layer 143 constituting the driving TFT 220, and a source 143s and a drain 143d are formed on both sides of the channel 143c.

Fifth Process (See FIG. 7): Process of Forming Photosensor Constituted by Second Thin Film Transistor Having Second Gate Electrode and Second Semiconductor Layer

In the same manner as the fourth process, SiN, SiO₂ or the like, which is used as the gate insulating film 12, is formed on the semiconductor layer 13 (second p-Si film), and a gate electrode 11 is formed thereon, thus forming the TFT functioning as the photosensor 100. A region of the semiconductor layer 13, which overlaps the gate electrode 11, is used as a channel 13c, and one conductivity type impurities of a high concentration are diffused onto both sides of the channel 13c, thus forming a source 13s and a drain 13d. At this time, the source side which serves as current outputting side may take a LDD structure.

Sixth Process (See FIG. 8): Process of Forming Pixel Including First Thin Film Transistor in Region Where First Thin Film Transistor is Formed, and Forming Display Portion Constituted by Pixels

Thereafter, interlayer insulating film 15 is formed on the entire surfaces of the semiconductor layers 13, 113, and 143, the gate insulating film 12 and the gate electrodes 11, 111, and 141 by sequentially laminating a SiO₂ film, a SiN film and a SiO₂ film in this order. Furthermore, a contact hole is formed so as to correspond to the drain 113d of the switching TFT, and a metal such as aluminum (Al) is filled in the contact hole, thus providing drain electrode 116 functioning also as a drain signal line 152. At the same time, a metal such as aluminum (Al) is filled in a contact hole formed so as to correspond to the drain 143d of the driving TFT, thus forming a driving power supply line 153 connected to a driving power supply.

Furthermore, a contact hole corresponding to the drain 13d of the photosensor 100 is formed, and thus a drain electrode 16 is formed. In the same manner described above, a metal such as aluminum (Al) is filled also in a contact hole corresponding to the source 143s of the driving TFT 220, and hence source electrode 158 is formed. A metal such as aluminum (Al) is filled also in a contact hole corresponding to the source 13s of the photosensor 100, thus forming a source electrode 18. Still furthermore, planarized insulating film 17 made of organic resin, a surface of which is planarized, is formed on the entire surface of the resultant structure.

In the driving TFT 220, a contact hole corresponding to the source electrode 158 is formed in the planarized insulating film 17, and an anode 161 obtained by giving a reflection function to ITO, IZO or the like is formed. Furthermore, in order to EL layer 165 from being divided by a step difference in an edge of the anode 161, second planarized film 56 is formed on the entire surface of the resultant structure, thus exposing a formation region of the EL layer 165. The EL layer 165 forms a hole transportation layer 162 composed of first and second transportation layers on the anode 161. Furthermore, a metallic mask having an opening is placed in a light emission region, and a light emission layer emitting a certain one color among R, G and B colors, which composes a display pixel, is deposited. Thereafter, the metallic mask is moved, and light emission layers emitting colors other than the certain one color are deposited. Thus, light emission layers 163 of R, G and B colors are formed.

Furthermore, electron transportation layer 164 is laminated, and cathode 166 made of magnesium-indium alloy, which has light permeability, is laminatedly formed, thus forming the display portion 200 and the light emission element 240. At this time, an organic EL layer 171 of the light emission element 240 (not shown) is also formed. Since the light emission layer 163 of the light emission element 240 may emit any color and is not required to emit different colors, the light emission layers 163 of all light emission elements 240 are formed when a light emission layer emitting any one of the colors R, G and B is formed. When the light emission layer 163 is monochrome and colorized by use of a color filter and a color changing layer, it is possible to fabricate all EL elements of the display portion 200 and the light emission element 240 by common material and structure.

In order to allow the light of the light emission element 240 to reach the photosensor 100, the reflection material 260 such as a mirror is formed as shown in FIG. 1, thus obtaining the display device shown in FIG. 1.

Next, a second embodiment will be described. In this embodiment of the present invention, a semiconductor layer having not only difference in the grain size of a crystal particle but also that anisotropy in a crystal length (average crystal length) may be used.

A schematic view of the device of this embodiment is the same as that in FIGS. 1 through 3, and descriptions are omitted. A method of obtaining a semiconductor layer having not only difference in the grain size of a crystal particle but also that the anisotropy in the crystal length will be described.

(1) CLC (CW-Laser Lateral Crystallization) Method

A CLC method is the one in which a DPSS (diode-pumped solid state) laser is radiated onto amorphous silicon and a crystal is grown in a scanning direction of the laser. According to this method, a crystal length of the crystal in the scanning direction is made longer by controlling a speed at which the laser is scanned.

(2) SELAX (Selectively Enlarging Laser X'Tallization) Method

A SELAX method is the one in which polysilicon having a small grain size of a crystal particle is formed by radiating an excimer laser onto amorphous silicon, and a solid state pulse laser is radiated onto the polysilicon, thus forming the polysilicon which is long in a scanning direction thereof.

(3) SLS (Sequential Lateral Solidification) Method

A SLS method is the one in which a line-shaped excimer laser is radiated onto amorphous silicon to grow a crystal which is long in a direction parallel to a scanning direction, and this crystal overlaps the crystal grown by the previous laser radiation a little, whereby the crystals are continuously formed. In the CLC and SELAX methods, while the lower-power solid state laser is used, the SLS method is a useful method because the excimer laser having power higher than that of the solid state laser is radiated in the SLS method.

The above described methods can obtain the semiconductor layers having the difference equal to the grain size of the crystal particle and the anisotropy in the crystal length because the difference of the energy given to the semiconductor layers is produced even when the laser is radiated onto the entire surface in the foregoing second step and the third process (polycrystallization process). The TFTs constituting a photosensor 100 are arranged so that the direction where the crystal length is long (the direction where the number of the crystal boundaries are small) and the electric conduction direction of the TFTs constituting the photosensor 100 (the source-drain direction) are parallel, and the electric conduction directions of driving TFTs 220 and switching TFTs 210 are arranged in a direction different from the electric conduction direction of the TFTs constituting the photosensor 100, for example, a vertical direction to the electric conduction direction of the TFTs for the photosensor 100. Where TFTs for driving light emission element 240 are present, also an electric conduction direction of these TFTs is set to be the same as that of the switching TFTs 210. Thus, it is possible to make the crystal length of the TFTs for the photosensor 100 different from those of other TFTs without masking (see FIG. 6) locally as described in the first embodiment.

The embodiment above corresponds to a structure in which all the crystals of the polycrystallized semiconductor layer are elongated in one direction, the electric conduction direction of the photosensor TFT is aligned in this elongation direction, and the electric conduction direction of the driving and switching TFTs is aligned in a direction different of the elongation direction, preferably, normal to the elongation direction. However, it is also possible that the semiconductor layer corresponding to the driving and switching TFTs of the pixel is crystallized to have a normal grain shape, i.e., not intentionally elongated in one direction, and that the semiconductor layer corresponding to the photosensor TFT is crystallized to have the elongated shape so that the sensor configuration can take advantage of this elongated crystal shape. Furthermore, when the photosensors are formed along two edges of the insulating substrate normal to each other, the corresponding semiconductor layers may be crystallized to have different elongation directions.

In this embodiment, the descriptions were made by taking the touch panel as an example. However, the display device is not limited to the touch panel, as long as the display device adopts the structure in which the photosensor 100 is formed on the same substrate in which the display portion 200 is formed. For example, the present invention can be applied to a display device in which a photosensor is provided on the same plane on which a display portion is formed, and a brightness of the display portion is adjusted by detecting external light.

As for the pixel TFT, the TFT for the photosensor, the TFT connected to the light emission element, if there is a gate electrode on their light receiving plane, it is difficult for them to receive light because of the existence of the gate electrode. Accordingly, the gate electrode should be provided opposite to the light receiving plane.

In the foregoing embodiment, though the descriptions of the pixel TFT, the TFT for the photosensor, and the TFT connected to the light emission element were made as to so-called a top gate type TFT, the same is true for a bottom gate type TFT in which the lamination order of the gate electrode, the gate insulating film and the semiconductor layer is inverse to that of the top gate type TFT.

The pixel TFT, the TFT for the photosensor, and the TFT connected to the light emission element need not to be the top gate type or the bottom gate type all together, and the combination of the top and bottom gate types may be adopted.

Furthermore, in the above described embodiment, the descriptions were made for the top emission type in which the light from the organic EL layer 165 is emitted in a reverse direction to the insulating substrate 10. The embodiment of the present invention is not limited to this, and a bottom emission type in which the light from the organic EL layer 165 is emitted via the insulating substrate 10 may be employed.

1. A display device comprising:
a display portion comprising a plurality of pixels, each of the pixels comprising a first thin film transistor comprising a first semiconductor layer, and
a photosensor comprising a second thin film transistor comprising a second semiconductor layer,
wherein a grain size of crystals forming the second semiconductor layer is larger than a grain size of crystals forming the first semiconductor layer.

2. A display device comprising:
a display portion comprising a plurality of pixels, each of the pixels comprising a first thin film transistor comprising a first semiconductor layer, and
a photosensor comprising a second thin film transistor comprising a second semiconductor layer,
wherein a crystal length in a predetermined direction of crystals forming the second semiconductor layer is longer than a crystal length in the predetermined direction of crystals forming the first semiconductor layer.

3. The display device of claim 1 or 2, further comprising an insulating substrate and additional photosensors, wherein each of the pixels further comprises an organic electroluminescent element, the pixels are arranged on the insulating substrate as a matrix, and the photosensor and the additional photosensors are disposed along an edge of the display portion.

4. The display device of claim 3, further comprising a plurality of light emission elements disposed on the insulating substrate along another edge of the display portion so that one of the light emission elements corresponds to one of the photosensors, and a reflection system which reflects light from the light emitting elements, allows the light to pass over the display portion and leads the light to the photosensors.

5. The display device of claim 1, wherein the grain size is provided as an average size of the crystals of the corresponding semiconductor layer observed over an unit area.

6. The display device of claim 2, wherein a total number of grain boundaries in an electric conduction direction of the second semiconductor layer is smaller than a total number of grain boundaries in an electric conduction direction of the first semiconductor layer.

7. A method of fabricating a display device, comprising:
forming an amorphous semiconductor layer on an insulating substrate;
crystallizing the amorphous semiconductor layer so as to form a first semiconductor layer of a first grain size and a second semiconductor layer of a second grain size that is larger than the first grain size;
forming a first thin film transistor comprising the first semiconductor layer;
forming a photosensor comprising a second thin film transistor comprising the second semiconductor layer; and
forming a pixel comprising the first thin film transistor in a display portion of the display device.

8. A method of fabricating a display device, comprising:
forming an amorphous semiconductor layer on an insulating substrate;
crystallizing the amorphous semiconductor layer so as to form a first semiconductor layer comprising crystals having a first crystal length in a predetermined direction and a second semiconductor layer comprising crystals having a second crystal length in the predetermined direction which is longer than the fist crystal length;
forming a first thin film transistor comprising the first semiconductor layer;
forming a photosensor comprising a second thin film transistor comprising the second semiconductor layer so that an electric conduction of the second thin film transistor is in the predetermined direction; and
forming a pixel comprising the first thin film transistor in a display portion of the display device.

9. The method of claim 7 or 8, wherein the amorphous semiconductor layer is crystallized by laser radiation.

10. The method of claim 7, wherein the first and second grain sizes are provided as an average size of the crystals of the corresponding semiconductor layer observed over an unit area.

11. The method of claim 7 or 8, further comprising forming, when the pixel is formed, a light emission element comprising same emission components as the pixel of the display portion and disposed at a periphery of the display portion.

12. The method of claim 7 or 8, wherein the first and second semiconductor layers, when the amorphous semiconductor layer is crystallized, each receive different amounts of energy given by laser radiation.

13. The method of claim 12, wherein the different amounts of energy are based on a difference in a total number of times of laser radiation to the corresponding amorphous semiconductor layer.

14. The method of claim 12, wherein the different amounts of energy are based on a difference in a scan speed of a laser during the laser radiation.

15. The method of claim 12, wherein the different amounts of energy are based on a difference in a power of a laser during the laser radiation.
